(19) United States
(12) Patent Application Publication
(10) Pub. No.: US 2026/0040982 A1
(43) Pub. Date: Feb. 5, 2026

(54) GLASS PACKAGE WITH LIQUID METAL SOCKETING

(71) Applicant: Intel Corporation, Santa Clara, CA (US)

(72) Inventors: Gang Duan, Chandler, AZ (US); Srinivas Venkata Ramanuja Pietambaram, Chandler, AZ (US); Jeremy D. Ecton, Gilbert, AZ (US); Brandon Christian Marin, Gilbert, AZ (US); Bohan Shan, Chandler, AZ (US)

(73) Assignee: Intel Corporation, Santa Clara, CA (US)

(21) Appl. No.: 18/794,645

(22) Filed: Aug. 5, 2024

(51) Int. Cl. H01L 23/13; H01L 23/14; H01L 23/498

(52) U.S. Cl. CPC H01L 23/13; H01L 23/147; H01L 23/49816; H01L 23/49827

(57) ABSTRACT

A packaging apparatus and methodology for a glass core package that can replace a BGA pinout with a well material perforated with through-holes filled with LM and protected by a thin layer of a dielectric material. The glass package with liquid metal (LM) socketing is to attach to a LM-compatible socket; the LM-compatible socket can be soldered to a main board or printed circuit board (PCB).

### BACKGROUND

System level heterogeneous integration has been getting a lot of attention due to its high potential for use in market niches such as, high-performance computing (HPC), supercomputing, autonomous driving, and machine learning applications. The high-performance computing demands of these markets further drives large form factor advanced packaging architectures, because the system level heterogenous integration can include compute tiles, input/output (I/O) modules, memory, power delivery, and thermal cooling solutions, to name just a few examples. Accordingly, it is desirable for packaging solutions to evolve to support the performance needs of these system level heterogenous integration applications.

### BRIEF DESCRIPTION OF THE DRAWINGS

FIG. 1 illustrates an exemplary glass package with liquid metal socketing for assembly, in accordance with various embodiments.

FIG. 2 illustrates features of a glass package, in accordance with various embodiments.

FIG. 3 illustrates the assembly of the components of FIG. 1, in accordance with various embodiments.

FIG. 4 illustrates through-hole shapes, in accordance with various embodiments.

FIG. 5 illustrates a simplified method for making and assembling a glass package with liquid metal socketing.

FIG. 6 is a top view of a wafer and dies that may be included in a microelectronic assembly, in accordance with any of the embodiments disclosed herein.

FIG. 7 is a simplified cross-sectional side view showing an implementation of an integrated circuit on a die that may be included in various embodiments, in accordance with any of the embodiments disclosed herein.

FIG. 8 is a cross-sectional side view of a microelectronic assembly that may include any of the embodiments disclosed herein.

FIG. 9 is a block diagram of an example electrical device that may include any of the embodiments disclosed herein.

### DETAILED DESCRIPTION

The following detailed description is merely exemplary in nature and is not intended to limit the application and uses. It may be evident that the novel embodiments can be practiced without every detail described herein. For the sake of brevity, well known structures and devices may be shown in block diagram form to facilitate a description thereof.

As demands for high performance computing (HPC) continue to rise, system level heterogeneous integration has become an important performance enabler. Realizing system level heterogenous integration requires addressing technical challenges, such as high interconnect densities, increased bandwidths, and improved power efficiency. A variety of different advanced packaging architectures have been deployed to address these technical challenges, and to enable a more effective way to perform die disaggregation/heterogeneous integration to shorten the time to market. Some example advanced packaging architecture solutions for system level heterogenous integration include die embedding and/or the use of silicon (Si) interposers to achieve the significantly higher package I/O counts and densities of the HPC market product performance needs.

Additionally, system level heterogeneous integration has been getting a lot of attention due to its extremely high potential for use in other market niches, such as supercomputing, autonomous driving, and machine learning applications. The high-performance computing demands of these markets further drives large form factor advanced packaging architectures, to support system level heterogenous integration of compute tiles, input/output (I/O), memory, power delivery, and thermal cooling solutions, to name just a few examples.

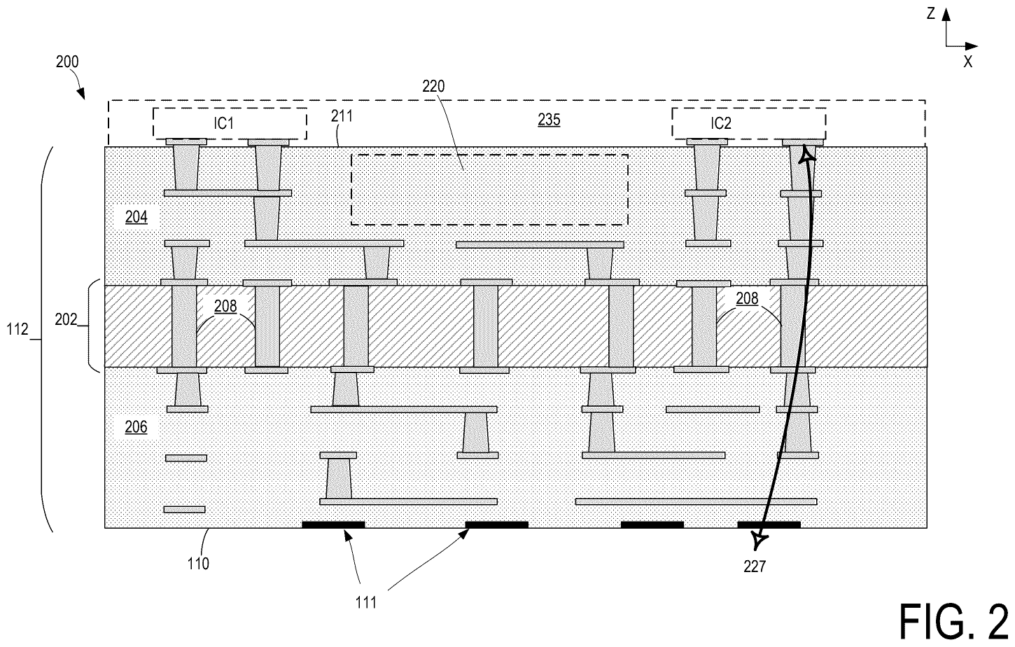

Moving into the advance packaging space, a package substrate with a glass core is often used (herein, the package substrate with a glass core may interchangeably be referred to as a “glass package,” “glass core package,” or a “hybrid component”). The glass package includes a layer of glass or the glass core, plus buildup above and below, wherein “buildup” comprises layers of dielectric with redistribution layers therein (see, e.g., FIG. 2). An assembled glass package can be a system or an apparatus. The glass core in the glass packages provides many advantages to a system, one of them being the ability to deliver greater than 8 times (8×) the silicon reticle size content integration in the same size package. However, in many available solutions, the package substrate-to-printed circuit board (PCB) interconnect is achieved using ball grid array (BGA) packaging technology and soldering the BGA package directly onto a PCB. With a large and ultra large form factor (ULFF) packages, the stress from the coefficient of thermal expansion (CTE) of the dies and silicon, and the limitations imposed by the BGA tolerance can adversely affect the yield and reliability of the final products.

The present disclosure provides a technical solution to the above-described problems, in the form of an advanced packaging technology comprising a glass package with liquid metal (LM) socketing. As is described in more detail below, embodiments introduce a packaging apparatus and methodology replacing a BGA pinout with an interface comprising a well material perforated with through-holes filled with LM and protected by a thin layer of a foam. The glass package with liquid metal (LM) socketing is to attach to a LM-compatible socket; the LM-compatible socket can be soldered to a main board or printed circuit board (PCB).

Exemplary embodiments will hereinafter be described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

The term “overlaid” (past participle of “overlay”) may be used to refer to a layer to describe a location and orientation for the layer but does not imply a method for achieving the location and orientation. For example, a first layer overlaid on a second layer, or overlaid on a component means that the first layer is spread across or superimposed on the second layer or component. Accordingly, a layer that is overlaid on a second layer may be viewed in a cross-sectional view as adjacent to the second layer.

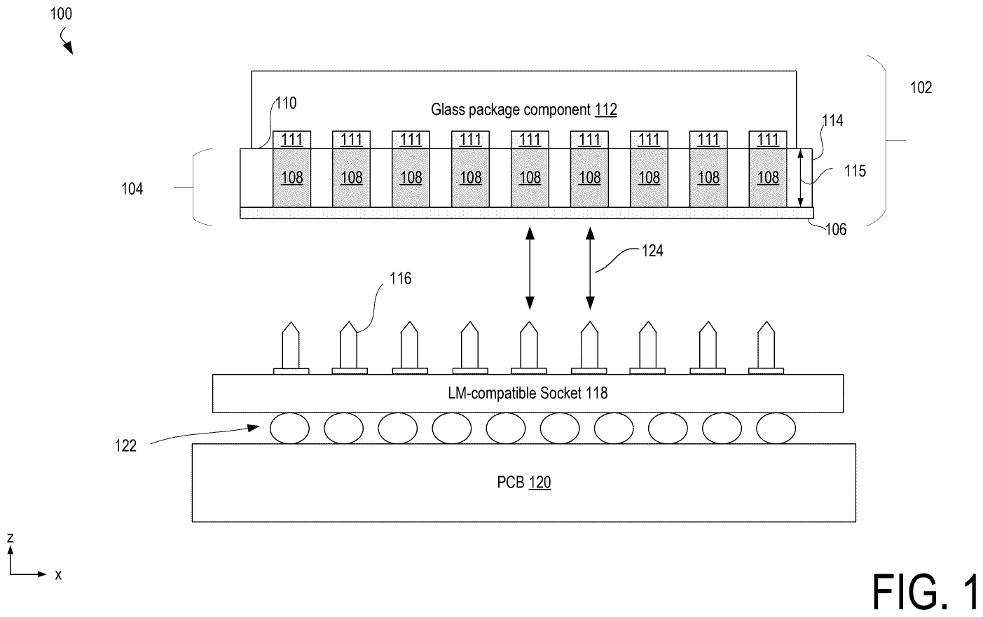

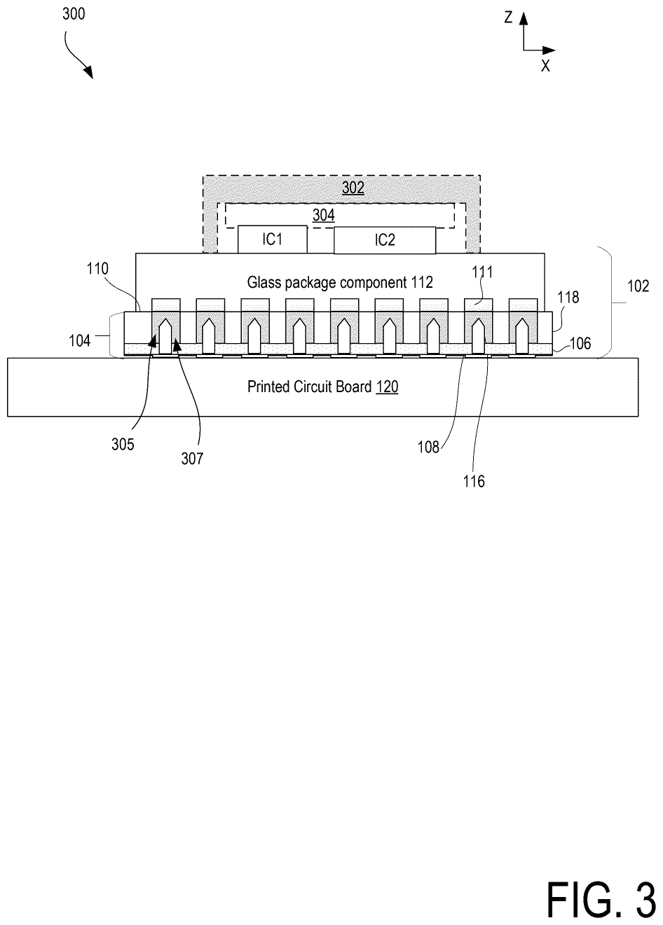

FIG. 1 is a simplified cross-sectional view of a system 100 depicting embodiments of components described herein. Some components of the system 100 are shown separated to clearly depict features and describe embodiments of components. The glass package component is simplified in FIG. 1 and is described in more detail in connection with FIG. 2. FIG. 3 provides an exemplary illustration of the components of the system 100 assembled together.

Embodiments of a glass package with liquid metal socketing 102 comprise a glass package component 112 with a liquid metal (LM) socketing interface 104. The glass package component 112 has a plurality of conductive contacts or metal pads 111 in an arrangement as a ball grid array (BGA); in various embodiments, the BGA arrangement can be characterized by a pinout with a pitch in a range between 0.05 millimeters (0.05 mm) to 1.5 millimeters (1.5 mm). The LM socketing interface 104 extends across the lower surface 110 of the glass package component 112. The LM socketing interface 104 comprises a layer of insulating material, also referred to as well material 114 that has formed therein a plurality of through-holes 108 or cavities. The through-holes 108 are arranged or aligned in a one-to-one association with the conductive pads (metal pads 111) on the glass package component 112. A thin layer 106 of another insulating material, or protectant layer, such as a polyethylene foam is overlaid on the lower surface.

A LM-compatible socket 118 comprises a plurality of pins 116; the pins 116 are arranged in accordance with the pinout arrangement of the glass package with liquid metal socketing 102, such that attaching the glass package with liquid metal socketing 102 onto the LM-compatible socket 118 as illustrated with the arrows 124 results in the pins 116 puncturing the thin layer 106 and a one-to-one mating of individual through-holes 108 and pins 116 (see, e.g., FIG. 3). In various embodiments, the LM-compatible socket 118 may be previously attached with solder bumps 122 to a main board or printed circuit board (PCB 120).

FIG. 2 illustrates a non-limiting example of a glass package component 200, as referenced herein. The glass package component 200 is sometimes referred to as a hybrid component, because it has a layer of glass or glass core 202, plus buildup above and below comprising layers of dielectric with redistribution layers therein. The glass package component 200 can be a system or an apparatus. In various embodiments, the glass package component 200 can be reconstituted into a wafer or panel for further assembly. The glass core 202 is a rectangular prism volume.

The glass core 202 comprises a layer of “glass material” or “glass.” As used herein, glass may comprise Silicon and Oxygen, as well as any one or more of Aluminum, Boron, Magnesium, Calcium, Barium, Tin, Sodium, Potassium, Strontium, Phosphorus, Zirconium, Lithium, Titanium, and Zinc. Non-limiting examples of glass include aluminosilicate, borosilicate, alumino-borosilicate, silica, and fused silica. In various embodiments, the glass may further include one or more additives, such as Al2O3, B2O3, MgO, CaO, SrO, BaO, SnO2, Na2O, K2O, SrO, P2O3, ZrO2, Li2O, Ti, and Zn.

In some embodiments, the glass comprises at least 23 percent Silicon and at least 26 percent Oxygen by weight, and further comprises at least 5 percent Aluminum by weight. In some embodiments, the glass may be a photosensitive glass that belongs to the lithium-silicate family of glass (e.g., a glass comprising lithium, silicon, and oxygen) comprising metallic particles, such as gold, silver, or other suitable metallic particles. The glass core 202 may comprise multiple glass sheets fused or bonded together with an adhesion layer. The glass in the glass core 202 does not include an organic adhesive and the glass does not include an organic material. In various aspects of the disclosure, the layer of glass may be referred to as a solid layer of glass, even when constructed with a plurality of sheets of glass fused together, with the sections or TGVs removed.

The composition of the glass core 202 may reflect the intended application. In some embodiments, it is advantageous for the glass material of the glass core 202 to have a CTE that approximates or matches that of target dies (e.g., match the CTE of the silicon in an IC die such as IC1 and IC2 attached thereto). In some embodiments, the glass material can be tailored to affect the CTE and thereby lower thermal stress at the interface with the one or more IC dies attached on the upper surface 211. In some embodiments, the dielectric material used for dielectric layers 204/206 can have a CTE that is close (e.g., within 10%) to that of silicon. In other embodiments, the dielectric material can be any type of epoxy molding compound.

In various embodiments, the glass core 202 may have a thickness (i.e., the Z direction in FIG. 2) that ranges from 20 microns+/−10% to 2 millimeters (mm)+/−10%. The glass core 202 may have a planar area (i.e., the Y-X directions in FIG. 1) that is defined by perimeter edges that are substantially orthogonal or perpendicular (i.e., 90 degrees plus or minus 18 degrees) to the planar area, the edges can have a length in a range of 10 millimeters (mm)+/−20% to 250 millimeters+/−20% (e.g., a panel can be 10 millimeters×10 millimeters up to 250 millimeters×250 millimeters).

In the embodiment of the glass core 202, the glass comprises a rectangular prism volume with sections removed, those sections being the through-glass vias 208. The glass core 202 comprises a plurality of through glass vias (TGVs 208), respectively to enable electrical communication from an upper surface of the glass core 202 to the lower surface of the glass core 202. The TGVs may comprise a liner and a conductive material, as is practiced in the art. The TGVs 208 are substantially orthogonal or perpendicular (i.e., 90 degrees plus or minus 18 degrees) to the upper surface 211.

There is a dielectric material (dielectric layer 204) with RDL therein on the upper surface of the glass core 202 and a dielectric material (dielectric layer 206) with RDL therein on the bottom surface of the glass core 202. Described differently, the glass core 202 is sandwiched between dielectric layers 204/206 that include respective redistribution layers (RDL); the dielectric layers 204/206 are substantially coplanar with the layer of glass, i.e., extending laterally left to right (along the X axis) above and below the glass core 202, as illustrated.

The dielectric layers 204/206 comprise a dielectric material, such as, a suitable nitride or oxide like silicon dioxide (SiO2), carbon-doped silicon dioxide (C doped SiO2, also known as CDO or organosilicate glass, which is a material that comprises silicon, oxygen, and carbon), fluorine-doped silicon dioxide (F-doped SiO2, also known as fluorosilicate glass, which is a material that comprises fluorine, silicon, and oxygen), or hydrogen-doped silicon dioxide (H-doped SiO2, which is a material that comprises silicon, oxygen, and hydrogen). In some embodiments, the dielectric material comprises a photo-imageable dielectric (PID). In some embodiments, the dielectric material comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df)).

The RDL embodies electrical interconnections and electrical paths, or conductive traces, layered and built into the dielectric layers, as is known in the art. As used herein, redistribution layers (RDL) comprise metal or conductive traces or interconnects that connect or provide electrical paths between one region in a glass package component 200 to another region and are sufficient for electrical communication and/or for supplying power and ground. The RDL may be implemented in a “core geometry,” such as a 9/12 geometry (meaning a conductive trace width of 9 microns and a spacing of 12 microns). The RDL may comprise a metal (e.g., copper, aluminum, nickel, cobalt, iron, tin, gold, silver, or combinations thereof) or another suitable conductive material. The RDL may have a thickness (measured in the Z direction in the figure) from about 1 micron to 10 microns. In various embodiments, the RDL may be substantially 5 microns. The RDL patterning may be performed using a modified semi-additive plating (MSAP) process, placing the RDL. Pillars or vias provide vertical connectivity between layers of RDL, and comprise conductive material, and may be the same material as the conductive traces.

Although dielectric layers 204/206 with RDL therein are each illustrated as one continuous dielectric layer, those with skill will appreciate that the dielectric layers often each comprise 2 or more sub-dielectric layers, in a 1:1 relationship with the number of RDL layers. For example, in FIG. 2, three RDL layers are depicted in dielectric layer 204 on the upper surface of the glass core 202 and four RDL layers are depicted in dielectric layer 206 below the glass core 202. This is a non-limiting example.

In practice, the glass package component 200 may be part or all of a larger microelectronic assembly or system. Accordingly, the dashed boxes indicate optional variations on the glass package component, e.g., having one or more integrated circuits (ICs) attached on the upper surface 211 of the glass package component 200, and/or having an embedded bridge component 220. At least one electrical path 227 may travel from a conductive contact on the upper surface 211 to a metal pad 111.

The metal pads 111 may be in a predefined arrangement on the backside of the glass package component 200. The predefined arrangement can be referred to as a pinout, and the pinout may vary as a function of the specific dies (IC1/IC2) in each application. The metal pads 111 enable electrical connections and communication between the dies in the glass package component 200 and other components in a microelectronic assembly or system, such as the PCB 120.

In various embodiments, the die may be overmolded with an encapsulant 235. The encapsulant can comprise a molding compound, dielectric materials, metal, ceramic, plastic, or a combination thereof.

In other embodiments, as illustrated in FIG. 3, a thermal management solution comprising a cooling component such as a vapor chamber, heat pipe, heat sink, or liquid-cooled cold plate 302 may be attached to a glass package component 200. As part of a thermal management solution, a thermal conduction layer interface material (TIM 304) may be located over the dies attached to the glass package component 200. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

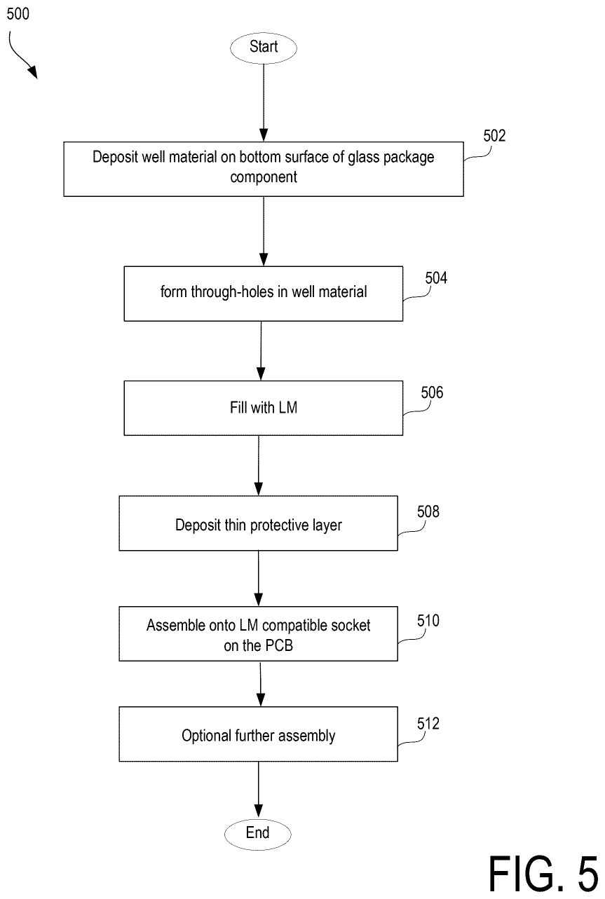

A method 500 for making and assembling a glass package with liquid metal socketing 102 is illustrated in FIG. 5 and referenced hereinbelow. The example method 500 may include additional or different operations, and the operations may be performed in the order shown or in another order. In some cases, one or more of the operations shown in FIG. 5 are implemented as processes that include multiple operations, sub-processes, or other types of routines. In some cases, operations can be combined, performed in another order, performed in parallel, iterated, or otherwise repeated or performed in another manner.

Initially, an integrated circuit (IC) die is selected to attach on an upper surface of the glass package component. The IC die has a coefficient of thermal expansion (CTE). During manufacture of the package component, the glass material used for the glass core 202 can be tailored, such that it approximates the CTE of the IC, plus or minus 10%.

At 502, the layer of the insulating material or well material 114 is overlaid or deposited on the bottom surface of the glass package component 112. The layer of well material 114 is also referred to herein as a polymer well. The well material has a thickness, thickness 115. In various embodiments, the thickness 115 of the well material is in a range of about 250 to about 400 microns (as used here, about means+/−10%). The well material is a non-conductive material and may comprise a composite material such as FR4; FR4 is a flame-retardant material used in printed circuit boards. The well material may comprise an epoxy with fillers, or a glass reinforced epoxy laminate or cloth. The well material may comprise liquid-crystal polymers.

At 504, a plurality of through-holes 108 are created in the layer of well material 114, arranged in accordance with the metal pads 111 on the glass package component 112. The individual through-holes 108 may be thought of as cavities or structures in the layer of well material 114. One end of a respective through-hole 108 abuts, provides direct access to, or is adjacent to, a respective metal pad 111. In some embodiments, sidewalls of the through-holes 108 are lined with a liner material (not shown). The through-holes 108 are substantially parallel to one another and substantially perpendicular (e.g., 90 degrees, plus or minus 10 degrees) to the lower surface 110 of the glass package component 112, as illustrated.

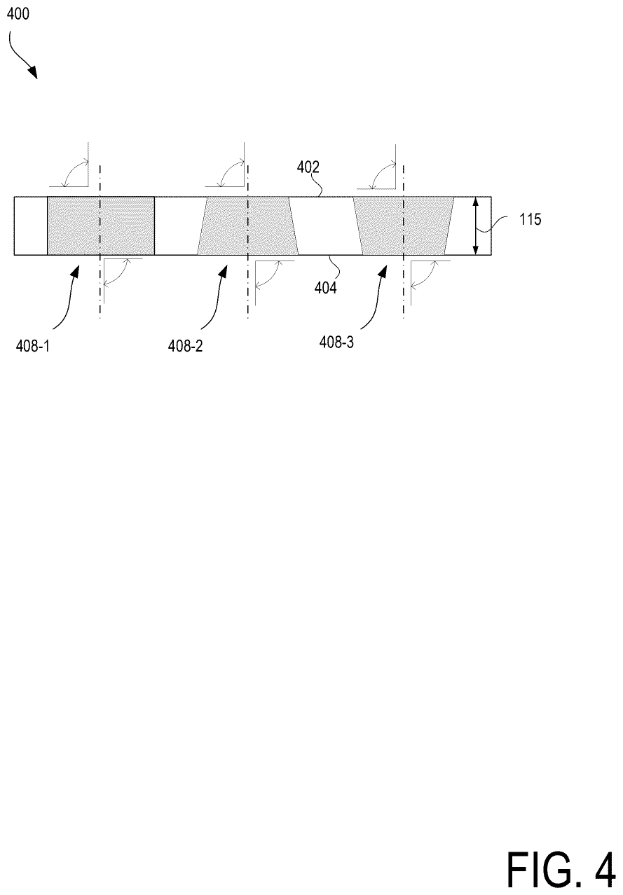

As is described in more detail in connection with FIG. 4, through-holes 108 may be cylindrical (through-hole 408-1, in which sidewalls are substantially perpendicular to the upper and lower surface), have tapered sidewalls that flare out more at a lower surface 404 than at an upper surface 402 (through-hole 408-2, having a more narrow diameter where it abuts the conductive contact or metal pad 111 of the glass package component than the diameter that abuts the thin layer 106 of foam), or have tapered sidewalls that flare out more at the upper surface 402 (a larger diameter where it abuts conductive contact or metal pad 111) than at the lower surface 404 (through-hole 408-3, where it abuts the thin layer 106 of foam). Various embodiments of the through-holes 108 (408-1, 408-2, 408-3) are generally radially symmetrical around an axis in the Z direction (as depicted in FIG. 4). As those with skill in the art will appreciate, the shape of the through-holes 108 (408-1, 408-2, 408-3) reflects the manufacturing process (e.g., chemical etch, mechanical, use of a carrier layer, etc.) used to create the through-holes in the polymer well or well material 114.

After the through-holes 108 (408-1, 408-2, 408-3) are created in the polymer well or well material 114, individual through-holes of the plurality of through-holes 108 are filled (at 506) with a liquid metal (LM). In some embodiments, “filled” may mean that at least 80% of the volume of a through-hole 108 is taken up with the LM. The LM extends from the upper surface 402 to the lower surface 404 of the polymer well or well material 114 and functions as interconnect media by electrically contacting a respective metal pad 111. In various embodiments, the liquid metal (LM) can comprise any suitable liquid metal that is liquid at normal operating temperatures of a substrate assembly. In some embodiments, the LM comprises gallium or an alloy of gallium, such as, for example, alloys of gallium and indium, eutectic alloys of gallium, indium, and tin, and eutectic alloys of gallium, indium, and zinc. In various applications, the LM may be Ga₂O₃. In various embodiments of a system 100, the LM of an individual through-hole 108 is sufficient to electrically couple to a respective metal pad 111.

At 508, after the through-holes are filled with LM, a thin layer 106 of a second insulating or dielectric material, often called a “foam,” is overlaid on the lower surface 404. Upon completion of 508, individual through-holes 108 have LM therein that is in electrical contact with a metal pad 111 at one end, and have an opposite end covered by the thin layer 106 of the second insulating material. The purpose of the thin layer 106 is to be protective, to hold the respective LM in the through-hole 108 in place, and to provide a seal that is puncturable by a pin 116 in the LM-compatible socket 118. Accordingly, the thin layer 106 (often, a foam) comprises a material that a pin 116 can puncture when components are pressed together as indicated with arrows 124. Example materials for the thin layer 106 include polyethylene, polyurethane, and other similar foams (materials); the thin layer 106 is to provide (1) a protective barrier, (2) a puncture-extract mechanism, and (3) resist moisture transmission. In a non-limiting example, the thin layer 106 has a thickness of 1 micron+/−10%. In some embodiments, an adhesive layer can be implemented between the thin layer 106 of foam and the LM.

Although the tasks at 502-508 are described as being distinct, in various embodiments, they may be performed all at once. Also, 502-504 may be combined, meaning that the well material may be deposited with a through-hole pattern in it already, something like laying down a lattice structure. In various embodiments, after 508, the resulting pitch and arrangement of through-holes filled with LM (i.e., “pinout”) can be substantially the same as an industry-standard ball grid array (BGA) pitch.

With reference again to FIGS. 1 and 3, the focus now turns to the LM-compatible socket 118. As shown, the LM-compatible socket 118 includes a plurality of surface pins 116 that are electrically coupled thereto. The plurality of pins 116 includes a pinout that is arranged for a 1×1 correspondence with the LM filled through-holes 108 on the glass package with liquid metal socketing 102. The surface pins 116 individually include a sharp end as shown in FIG. 1. In various embodiments, the pins 116 comprise a conductive metal, such as copper. In other embodiments, the pins 116 comprise copper with an ENIG (Emersion Nickel Gold) finish that is 1.25 microns thick+/−10%.

At 510, the glass package with liquid metal socketing 102 is assembled onto the LM compatible socket 118. At 510, this may include first selecting the LM compatible socket 118 comprising a plurality of pins extending upward and arranged in the BGA pinout and may further include solder-attaching the socket to a printed circuit board (PCB).

The glass package component is attached to the socket, such that individual pins insert into respective through-holes and contact LM. Individual pins 116 are configured to pierce the thin layer of foam and insert into a respective through-hole 108 in the polymer well or well material 114, contact the LM in the through-hole 108, and thereby complete an electrical connection with a respective metal pad 111. Collectively, a plurality of pins 116 are configured to pierce the thin layer of foam on the well material 114, causing individual pins of the plurality of pins 116 to be in physical contact with the LM in a respective through-hole 108, such that there is a one-to-one correspondence between pins 116 and through-holes 108, and to thus enable electrical contact between the metal pads 111 of the glass package component 112 and the PCB 120. Advantageously, assembly at 510 does not require a reflow process, and therefore, does not invoke issues with heat.

The practice of this disclosure can be confirmed with visual or cross-sectional inspections of the final product, as enhanced with an XSEM image. The well material 114 with the LM filled through-holes 108 can be identified on a glass core package. Embodiments may additionally be attached to an LM-compatible socket, as described in connection with FIG. 3.

In various aspects of the disclosure, the LM-compatible socket 118 may already be attached to a main board, or printed circuit board (PCB) 120, such as, with solder bumps 122. The PCB 120 may include multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the main board or PCB 120. As such, the system 100 may be all or part of a larger microelectronic assembly or system 300.

At 510. provided embodiments advantageously increase the tolerance for inaccuracy during assembly of the glass package component 112 to the PCB 120 than similar BGA assemblies. This advantage occurs because the diameter of the through-holes can be larger than the thickness of the surface pins 116, creating a roominess or tolerance (indicated in the X-direction in FIG. 3 by arrow 305 and 307, and it may be appreciated that this same tolerance may extend in the Y direction). Higher pin count glass package components 112 often mean a larger package size, more IC die, and more power connections between the PCB 120 and the IC dies; therefore, relief in tolerance for inaccuracy during assembly improves assembly yield and reliability, which is more valuable as package size increases. In practice, some of the contemplated glass package components 112 have a package dimensions of 120 millimeters×120 millimeters and 6,600 pins or more, and other contemplated glass package components 112 have a package size of 250 mm by 250 mm, for example, when a glass panel is singulated into just four packages.

A package/microclectronic assembly/system 300 comprising the glass package component 200 may have its functionality informed by the integrated circuit dies attached thereto (e.g., IC1, IC2). The dies may be packaged or unpacked integrated circuit products as described herein. In some embodiments, the IC1/IC2 dies can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the dies can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. In practice, the dies IC1/IC2 may represent multiple separate integrated circuit dies addressing different portions of the overall functionality of the glass package component 200, in these scenarios, the separate integrated circuit dies can be referred to as “chiplets.” In embodiments where the dies comprise multiple chiplets, interconnections between the chiplets can be provided by the package substrate, one or more silicon interposers, one or more silicon bridges embedded in the package substrate (such as Intel® embedded multi-die interconnect bridges (EMIBs)), or combinations thereof.

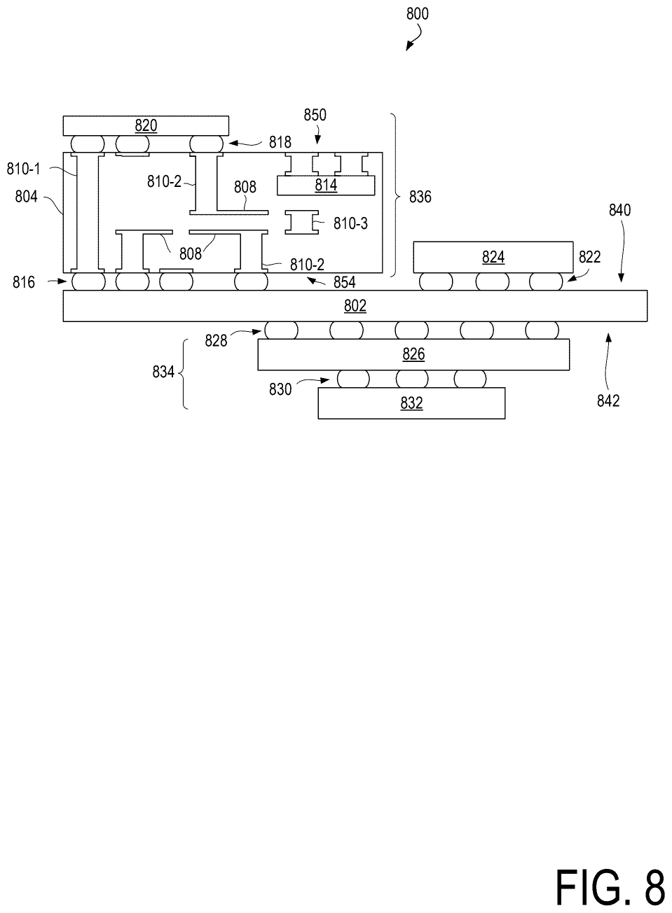

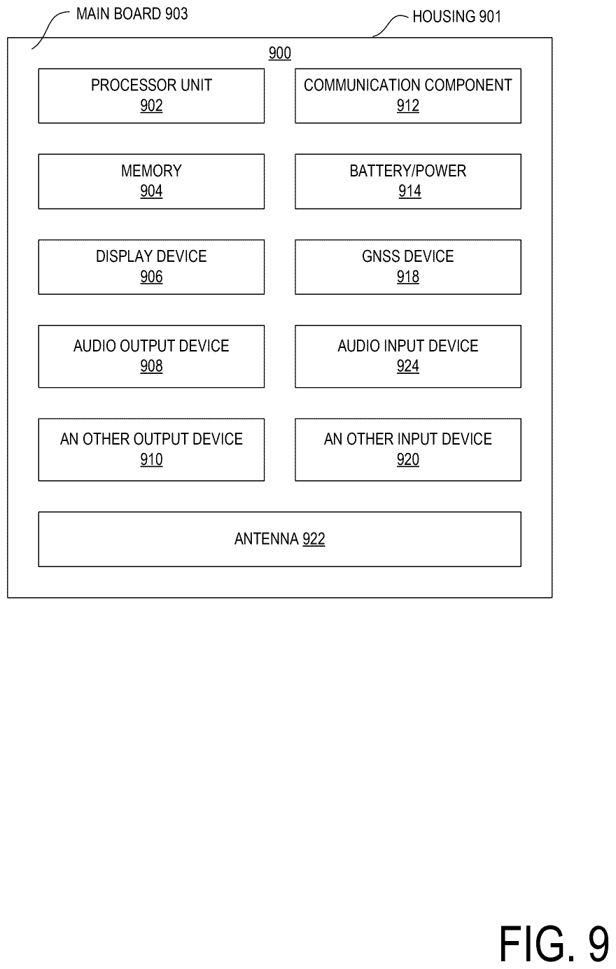

At 512, optional further assembly may be performed. Non-limiting examples include creating systems or microelectronic assemblies such as are illustrated in connection with FIG. 8, and/or devices or products as are illustrated in connection with FIG. 9.

Accordingly, various non-limiting embodiments of a glass package with LM socketing have been described. The provided embodiments advantageously use a liquid metal (LM) filled well material (such as a polyimide layer) in a BGA replacement strategy. The LM is desirable as it has a high clastic characteristic, is relatively easy to cast and mold, provides a high wear resistance, and has a relatively good conductivity. The PCB can be assembled with a LM compatible socket with surface pins such that a pick and place assembly can be done without needing a reflow step. Averting the reflow step increases the ability to repair and replace the assemblies.

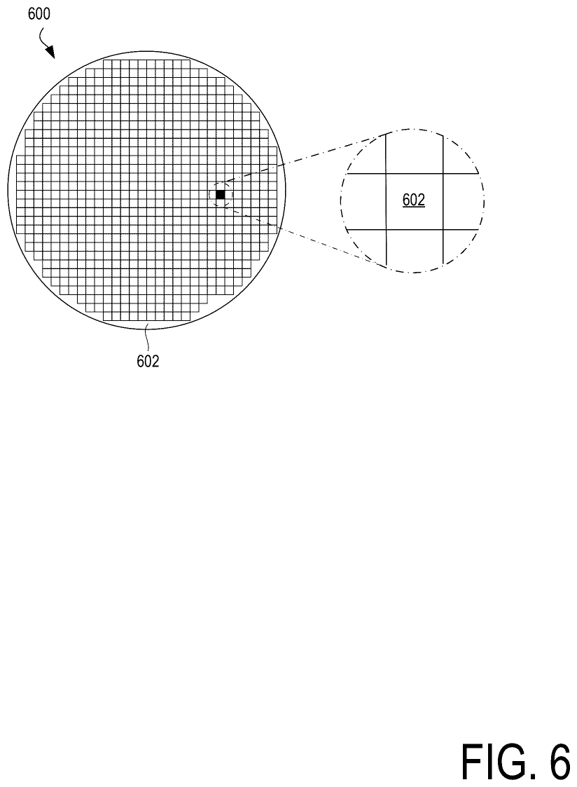

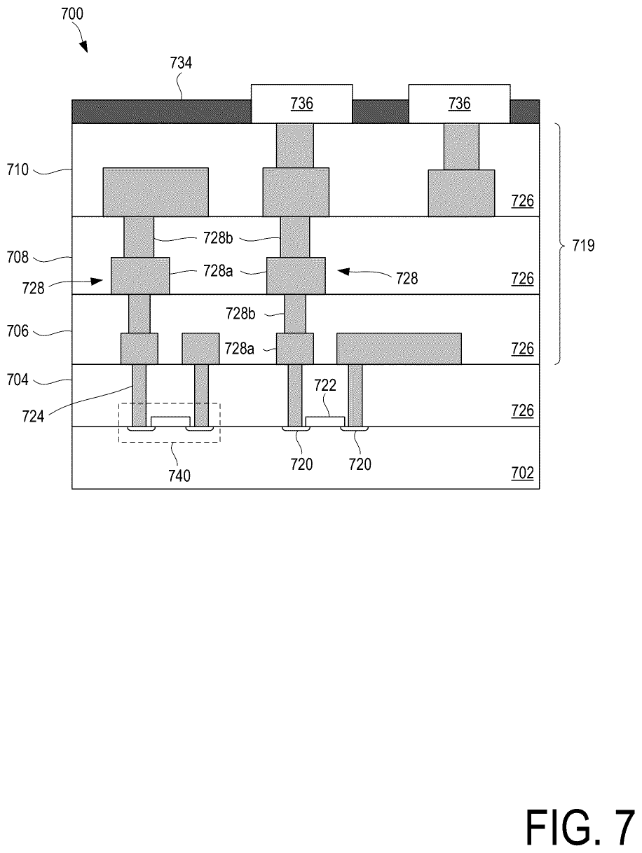

FIG. 6 is a top view of a wafer 600 and dies 602 that may be included in any of the embodiments disclosed herein. The wafer 600 may be composed of semiconductor material and may include one or more dies 602 formed on a surface of the wafer 600. After the fabrication of the integrated circuit components on the wafer 600 is complete, the wafer 600 may undergo a singulation process in which the dies 602 are separated from one another to provide discrete “chips” or destined for a packaged integrated circuit component. The individual dies 602, comprising an integrated circuit component, may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 602. For example, a memory array formed by multiple memory devices may be formed on a same die 602 as a processor unit (e.g., the processor unit 902 of FIG. 9) or other logic that is configured to store information in the memory devices or execute instructions stored in the memory array. In some embodiments, a die 602 may be attached to a wafer 600 that includes other die, and the wafer 600 is subsequently singulated, this manufacturing procedure is referred to as a die-to-wafer assembly technique.

FIG. 7 is a cross-sectional side view of an integrated circuit 700 that may be included in any of the embodiments disclosed herein. One or more of the integrated circuits 700 may be included in one or more dies 602 (FIG. 6). The integrated circuit 700 may be formed on a die substrate 702 (e.g., the wafer 600 of FIG. 6) and may be included in a die (e.g., the die 602 of FIG. 6).

The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit 700 may be used. The die substrate 702 may be part of a singulated die (e.g., the dies 602 of FIG. 6) or a wafer (e.g., the wafer 600 of FIG. 6).

The integrated circuit 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720.

The gate 722 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may comprise a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be conducted to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuits having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the interconnect structures 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit 700 with another component (e.g., a printed circuit board). The integrated circuit 700 may include additional or alternate structures to route the electrical signals from the interconnect layers 706-710; for example, the conductive contacts 736 may include other analogous features (e.g., posts) that route the electrical signals to external components.

In some embodiments in which the integrated circuit 700 is a double-sided die, the integrated circuit 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit 700 from the conductive contacts 736.

In other embodiments in which the integrated circuit 700 is a double-sided die, the integrated circuit 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit 700 from the conductive contacts 736. In some embodiments, TSVs extending through the substrate can be used for routing power and ground signals from conductive contacts on the opposite side of the integrated circuit 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuits 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 8 is a cross-sectional side view of a microelectronic assembly 800 that may include any of the embodiments disclosed herein. The microelectronic assembly 800 includes multiple integrated circuit components disposed on a circuit board 802 (which may be a motherboard, system board, mainboard, etc.). The microelectronic assembly 800 may include components disposed on a first face 840 of the circuit board 802 and an opposing second face 842 of the circuit board 802; generally, components may be disposed on one or both faces 840 and 842.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. The microelectronic assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpackaged integrated circuit component that includes one or more integrated circuit dies (e.g., the die 602 of FIG. 6, the integrated circuit 700 of FIG. 7) and/or one or more other suitable components.

The unpackaged integrated circuit component 820 comprises solder bumps attached to contacts on the die. The solder bumps allow the die to be directly attached to the interposer 804. In embodiments where the integrated circuit component 820 comprises multiple integrated circuit dies, the dies can be of the same type (a homogeneous multi-die integrated circuit component) or of two or more different types (a heterogeneous multi-die integrated circuit component). In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies are sometimes referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof. A packaged multi-die integrated circuit component can be referred to as a multi-chip package (MCP) or multi-chip module (MCM).

Generally, the interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on the first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

FIG. 9 is a block diagram of an example electrical device 900 that may include one or more of the embodiments disclosed herein. For example, any suitable ones of the components of the electrical device 900 may include one or more of the microelectronic assemblies 800, integrated circuit components 820, integrated circuits 700, integrated circuit dies 602, or structures disclosed herein. A number of components are illustrated in FIG. 9 as included in the electrical device 900, but any one or more of these components may be omitted or duplicated, as suitable for the application. In some embodiments, some or all the components included in the electrical device 900 may be attached to one or more motherboards, mainboards, printed circuit boards 903, or system boards. In some embodiments, one or more of these components are fabricated onto a single system-on-a-chip (SoC) die. In various embodiments, the electrical device 900 is enclosed by, or integrated with, a housing 901.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 94 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 900 can comprise one or more processor units 902 that are heterogeneous or asymmetric to another processor unit 902 in the electrical device 900. There can be a variety of differences between the processor units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. Various changes can be made in the function and arrangement of elements without departing from the scope of the disclosure as set forth in the appended claims and the legal equivalents thereof.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB).

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps or leads attached to the package substrate for attaching the packaged integrated circuit component to a printed circuit board or motherboard.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

### EXAMPLES

What is claimed is:

1. An apparatus, comprising:
a package substrate comprising a glass core and an arrangement of conductive pads on a lower surface, wherein the glass core comprises a rectangular prism volume defined by a planar area enclosed by one or more edges that are substantially orthogonal to the planar area;
a first insulating material extending across the lower surface of the package substrate;
a plurality of through-holes formed in the first insulating material in accordance with the arrangement of the conductive pads, and having liquid metal (LM) therein, such that the LM in an individual through-hole is electrically coupled to a respective conductive pad; and
a layer of a second insulating material extending across the first insulating material and across the LM.

2. The apparatus of claim 1, further comprising:
a first integrated circuit die attached on an upper surface of the package substrate;
a second integrated circuit die attached on the upper surface of the package substrate; and
wherein the glass core comprises a plurality of through-glass vias (TGVS) to enable electrical communication from the upper surface of the package substrate to the conductive pads on the lower surface.

3. The apparatus of claim 1, wherein the first insulating material comprises a polymer.

4. The apparatus of claim 1, wherein the second insulating material comprises a polyethylene foam.

5. The apparatus of claim 1, wherein the plurality of through-holes is at least 6,600 through-holes.

6. The apparatus of claim 1, wherein the first insulating material has a thickness in a range of 250 microns+/−10% to 400 microns+/−10%.

7. The apparatus of claim 1, wherein the LM comprises gallium, an alloy of gallium, a eutectic alloy of gallium, indium, and tin, or a eutectic alloy of gallium, indium, and zinc.

8. The apparatus of claim 1, wherein the second insulating material has a thickness of 1 micron+/−10%.

9. The apparatus of claim 1, wherein through-holes have sidewalls that are tapered such that they have a narrower diameter at the respective conductive pad than at the second insulating material.

10. The apparatus of claim 1, wherein through-holes have sidewalls that are tapered such that they have a narrower diameter at the second insulating material than at the respective conductive pad.

11. The apparatus of claim 1, wherein through-holes have sidewalls that are substantially perpendicular to the lower surface.

12. The apparatus of claim 1, further comprising:
a socket attached to the package substrate;
wherein the socket comprises pins arranged in a one-to-one correspondence with the plurality of through-holes; and
wherein individual pins are inserted into respective through-holes.

13. A multi-die assembly, comprising:
a package substrate comprising a glass core, an upper surface, and a lower surface;
two or more integrated circuit (IC) die attached on the upper surface;
a ball grid array (BGA) arrangement of conductive pads on the lower surface;
a plurality of through-glass vias (TGVS) in the glass core, to enable electrical communication from the two or more IC die on the upper surface to the conductive pads on the lower surface;
a polymer well extending across the lower surface of the package substrate;
a plurality of through-holes formed in the polymer well, individual through-holes aligned with respective conductive pads, and having gallium therein;
wherein, the gallium in an individual through-hole is electrically coupled to a respective conductive pad; and
a polyimide layer extending across the polymer well and across the gallium.

14. The multi-die assembly of claim 13, wherein the package substrate has package dimensions of 120 millimeters×120 millimeters.

15. The multi-die assembly of claim 13, wherein the package substrate has at least 6,600 through-holes.

16. The multi-die assembly of claim 13, further comprising:
a socket electrically coupled to the lower surface of the package substrate;
wherein the socket comprises pins arranged in a one-to-one correspondence with the plurality of through-holes; and
wherein individual pins are inserted into respective through-holes.

17. The multi-die assembly of claim 16, further comprising:
a printed circuit board (PCB); and
wherein the socket is solder attached to the PCB.

18. A method, comprising:
depositing a polymer well material on a bottom surface of a glass package component, wherein the glass package component has metal pads arranged in a ball grid array (BGA) pinout;
forming through-holes in the polymer well material, the through-holes arranged in a one-to-one correspondence with the metal pads in the glass package component;
filling the through-holes with liquid metal (LM); and
overlaying a protective layer of polyethylene on the polymer well material and the LM.

19. The method of claim 18, further comprising:
selecting an integrated circuit (IC) die to attach on an upper surface of the glass package component, the IC die having a coefficient of thermal expansion (CTE); and
tailoring a glass material used for a glass core in the glass package component, such that it approximates the CTE plus or minus 10%.

20. The method of claim 18, further comprising:
selecting a socket comprising a plurality of pins extending upward and arranged in the BGA pinout;
solder-attaching the socket to a printed circuit board (PCB);
attaching the glass package component to the socket, such that individual pins insert into respective through-holes and contact LM.
